(19) United States
(12) Patent Application Publication
(10) Pub. No.: US 2011/0276290 A1
(43) Pub. Date: Nov. 10, 2011

(54) Device for counting and storing automatically number of times of usage of cell

(76) Inventor: Chih-Peng Chang, Taichung City (TW)

(21) Appl. No.: 12/800,107

(22) Filed: May 7, 2010

(51) Int. Cl. G01R 31/36

(52) U.S. Cl. 702/63

(57) ABSTRACT

A device for counting and storing automatically the number of times of usage of a cell is provided. The device essentially includes at least a battery, a current sensor, a microprocessor, a memory unit, and a communication interface. Electrical connection is provided between the microprocessor and other components. The microprocessor, coupled with the current sensor, determines a time to start or stop counting, adds up the calculated charging and discharging duration, and sends the total duration to the memory unit. An external device can be connected to the microprocessor via the communication interface for reading from the memory unit the accumulative total of the charging and discharging duration, and obtain the number of times of the full charging and the full discharging of the battery by formula-based conversion. The device enables users and maintenance technicians to understand the past usage of the cell, and provides reference for warranty maintenance.

### BACKGROUND OF INVENTION

1. Field of the Invention

The present invention relates to a device for measuring the usage of cells, and more particularly, to a device for counting and storing automatically the number of times of usage of a cell by counting time automatically and memorizing/storing the time counted through current sensing so as to calculate the duration and number of times a battery was charged and discharged and thus provide references for maintenance of the battery.

2. Description of the Prior Art

Due to technological advancement and development, various novel technologies are developed and applied so as to enhance the sophistication and quality of products. With oil prices escalating and green awareness rising, environmentally friendly product R&D has never slowed down. Being gasoline-dependent, vehicles are always the focus of heavily funded R&D. As a result, electric vehicles, electric motorcycles, and electric bicycles are developed. Short battery life and power-related problems are identified as existing bottlenecks in the development of electric vehicles. By Contrast, electric motorcycles and electric bicycles are in their heyday in terms of mass production and commercialization.

Needless to say, a battery is required for the aforesaid electricity-driven vehicles. It is well known that battery capacity decay occurs in the course of repeated charged-discharged cycles, regardless of the types of the batteries, not to mention that every battery has an expected service life. The expected service life of a battery, however, is changeable, depending on usage (the number of charged-discharged cycles) and user behavior. Electric vehicle manufacturers have no way of knowing how consumers use batteries installed in purchased electric vehicles, though knowledge of this kind is otherwise important to electric vehicle manufacturers in providing maintenance service for the purchased electric vehicles. Hence, electric vehicle manufacturers nowadays often set a warranty term starting from the dates the batteries are purchased by consumers. Expiry of a warranty term of a battery is the criterion against which an electric vehicle manufacturer evaluates and determines whether to provide maintenance service for the battery with a dwindling capacity which affects the range of an electric vehicle using the battery. The drawback of the above mentioned is that the electric vehicle manufacturer is unable to further investigate whether the battery has been damaged because of an intrinsic reason or because of a user's improper operation. As a result, the electric vehicle manufacturer cannot provide reasonable warranty maintenance according to actual usage.

In conclusion, conventional battery warranty maintenance is not governed by objective standards, because of variable usage, and in consequence retailers or manufacturers are likely to dispute with users over warranty maintenance.

### SUMMARY OF INVENTION

It is a primary objective of the present invention to provide a device for counting and storing automatically the number of times of usage of a cell by detecting the charging and discharging of the cell automatically, adding up duration of the charging and discharging of the cell automatically and storing the total of the duration in a memory, thereby providing references for manufacturers to read data related to actual usage of the cell, such as the duration and the number of times a battery was charged and discharged.

Another objective of the present invention is to provide a device for counting and storing automatically the number of times of usage of a cell such that, by calculating, adding up, storing, and recording the duration and the number of times of charging and discharging, manufacturers can directly set forth a basis for determining whether to provide warranty maintenance according to the duration or the number of times of charging and discharging, so as to enhance the reasonableness of the contents of warranty maintenance.

Yet another objective of the present invention is to provide a device for counting and storing automatically the number of times of usage of a cell such that, by calculating, adding up, storing, and recording the duration and the number of times of charging and discharging, manufacturers can investigate into the problems with a battery and use data stored therein as references for product R&D.

In order to achieve the above and other objectives, the present invention provides a device for counting and storing automatically the number of times of usage of a cell. The device essentially includes at least a battery, a current sensor, a microprocessor, a memory unit, and a communication interface. Electrical connection is provided between the microprocessor and other components. The microprocessor, coupled with the current sensor, determines a time to start or a time to stop counting, adds up the calculated charging and discharging duration, and sends the total duration to the memory unit. An external device can be connected to the microprocessor via the communication interface so as to read from the memory unit the accumulative total of the duration of the charging and discharging of the cell, and obtain the number of times of the full charging and the full discharging of the battery by formula-based conversion.

### BRIEF DESCRIPTION OF THE DRAWINGS

The present invention as well as a preferred mode of use, further objectives and advantages thereof will best be understood by reference to the following detailed description of illustrative embodiments when read in conjunction with the accompanying drawings, wherein:

FIG. 1 is a block diagram of the present invention.

### DETAILED DESCRIPTION OF THE PREFERRED EMBODIMENT

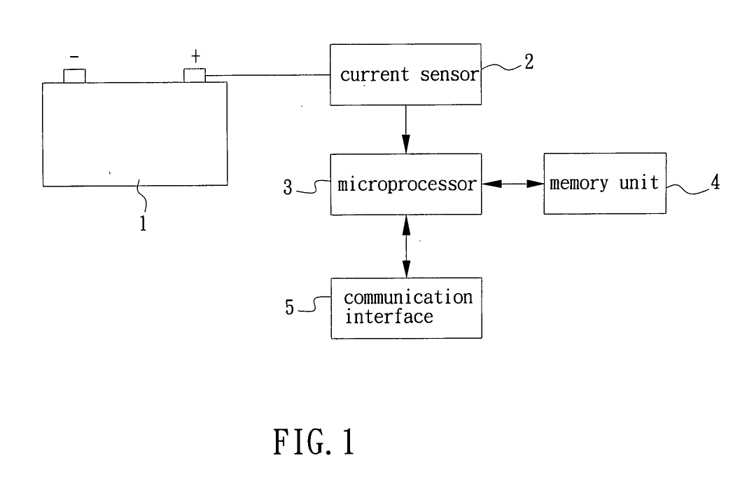

Referring to FIG. 1, there is shown a block diagram of the present invention. As shown in the drawing, the present invention provides a device for counting and storing automatically the number of times of usage of a cell. The device essentially comprises a battery 1, a current sensor 2, a microprocessor 3, a memory unit 4, and a communication interface 5. Electrical connection is provided between the microprocessor 3 and the battery 1, between the microprocessor 3 and the current sensor 2, between the microprocessor 3 and the memory unit 4, and between the microprocessor 3 and the communication interface 5. The current sensor 2 is disposed between the battery 1 and the microprocessor 3 and configured to detect the charging and discharging of the battery 1 automatically, generate a signal according to the result of detection, and send the signal to the microprocessor 3. The microprocessor 3 determines a time to start counting or a time to stop counting according to the signal from the current sensor 2, adds up the calculated duration of charging and discharging, and sends the total duration to the memory unit 4 for storage. An external device (not shown) can be connected to the microprocessor 3 via the communication interface 5 so as to read from the memory unit 4 the accumulative total of the duration of the charging and discharging of the cell, and obtain the number of times of the full charging and the full discharging of the battery by formula-based conversion.

Given the aforesaid framework, once a user starts charging and discharging a cell, the current sensor 2 which is capable of automatic detection will trigger the microprocessor 3 to count time unless and until the user stops charging and discharging the cell. If the user stops charging and discharging the cell, the current sensor 2 will instruct the microprocessor 3 to stop counting and store the accumulative duration of charging and discharging in the memory unit 4. The cumulative sum of the duration of charging and discharging in previous instances thereof is calculated in minutes by the microprocessor 3 and stored in the memory unit 4. The number of times of usage of a cell is calculated by multiplying the cumulative sum of the duration of charging and discharging by the defined duration of full charging and then by the capacity decay rate.

Given the aforesaid framework, well-equipped manufacturers not only directly read related charging and discharging data stored in the battery 1 to thereby fully understand the actual usage of the battery 1 after purchase, but also dispense with the conventional way of providing warranty maintenance when it was impossible to gain insight into the actual usage of the battery 1, that is, providing warranty maintenance only before expiry of a specific deadline. The present invention provides a device for counting and storing automatically the number of times of usage of a cell so as to obtain the accumulative duration of the charging and discharging of the cell in a realistic and fair manner; in so doing, the standards of warrant maintenance service provided by manufacturers are impartial and just to consumers and the manufacturers and unlikely to bring about disputes.

The communication interface 5 of the present invention is any communication interface in wide use, such as an I²C-bus, a serial peripheral interface (SPI), or a universal asynchronous receiver transmitter (UART), which provides the same function.

Hence, given the aforesaid framework, the present invention enables the charging and discharging of a battery to be automatically detected and accumulatively recorded so as to gain insight into the actual usage of the battery. In so doing, manufacturers or retailers calculate the term of warranty maintenance service according to parameters which are most closely correlated with the service life of a battery, that is, the number of times of charging and discharging, and the duration of charging and discharging. Once the battery needs warranty maintenance service, the manufacturers or retailers will use a communication interface to read related data stored in the battery to therefore easily understand the usage of the battery and determine whether the number of times of charging and discharging and the duration of charging and discharging meet the standards of warranty maintenance service provided by the manufacturers. In so doing, the standards of warranty maintenance service are objective, fair, just, and free of consumer disputes. Furthermore, related information acquired from a malfunctioning battery provides references for manufacturers in undertaking battery R&D.

In conclusion, the present invention provides a device for automatically counting and storing the number of times of usage of a cell so as to automatically record and store the number of times of the charging and discharging of the battery and the duration of the charging and discharging of the battery, thus allowing manufacturers to provide novel, fair, and just standards of warranty maintenance service and reduce unnecessary consumer disputes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A device for counting and storing automatically a number of times of usage of a cell, comprising a battery, a current sensor, a microprocessor, a memory unit, and a communication interface, wherein electrical connection is provided between the microprocessor and the battery, between the microprocessor and the current sensor, between the microprocessor and the memory unit, and between the microprocessor and the communication interface, the current sensor being disposed between the battery and the microprocessor and configured to automatically detect charging or discharging of the battery, to generate a signal according to a result of detection, and to send the signal to the microprocessor, and the microprocessor being configured to determine a time to start counting or a time to stop counting according to the signal from the current sensor, to add up calculated duration of charging and discharging, and to send the total duration to the memory unit for storage, wherein the microprocessor is connected to an external device via the communication interface.

2. The device of claim 1, wherein a cumulative sum of the duration of charging and discharging in previous instances thereof is calculated in minutes by the microprocessor and stored in the memory unit.

3. The device of claim 1, wherein the number of times of usage of the cell is calculated by multiplying a cumulative sum of the duration of charging and discharging by a defined duration of full charging and then by a capacity decay rate.

4. The device of claim 1, wherein the communication interface is an I²C-bus.

5. The device of claim 1, wherein the communication interface is a serial peripheral interface (SPI).

6. The device of claim 1, wherein the communication interface is a universal asynchronous receiver transmitter (UART).
